(19) United States
(12) Patent Application Publication
(10) Pub. No.: US 2015/0084171 A1
(43) Pub. Date: Mar. 26, 2015

(54) NO-LEAD SEMICONDUCTOR PACKAGE AND METHOD OF MANUFACTURING THE SAME

(71) Applicant: STMicroelectronics Pte. Ltd., Singapore (SG)

(72) Inventors: Yiyi Ma, Singapore (SG); Kim-Yong Goh, Singapore (SG); Xueren Zhang, Singapore (SG)

(73) Assignee: STMicroelectronics Pte. Ltd., Singapore (SG)

(21) Appl. No.: 14/034,121

(22) Filed: Sep. 23, 2013

(51) Int. Cl. H01L 23/495

(52) U.S. Cl. CPC H01L 23/49575
USPC 257/676; 438/123

(57) ABSTRACT

A non-lead (QFN) semiconductor package is disclosed. The package includes a die attach pad and a semiconductor die supported by the die attached pad. The semiconductor die includes a plurality of pads on an active surface thereof. The package further includes a plurality of terminal leads, an encapsulant that encapsulates the semiconductor die, and a redistribution layer including a plurality of interconnections electrically connecting the pads to the terminal leads. A method of making the package is also disclosed.

### BACKGROUND

1. Technical Field

This invention relates to a semiconductor package. More particularly, this invention relates to leadless or non-lead semiconductor packages, such as a quad flat non-lead (QFN) semiconductor package.

2. Description of the Related Art

Existing QFN semiconductor packages, such as that disclosed in U.S. Pat. No. 7,786,557, Hsieh et al., entitled “QFN Semiconductor Package”, includes a die attach pad having a recessed area. A semiconductor die is mounted inside the recessed area of the die attach pad. The package includes at least one row of inner terminal leads disposed adjacent to the die attach pad. First wires bond the inner terminal leads to the semiconductor die. The package also includes at least one row of extended, outer terminal leads disposed along the periphery of the QFN semiconductor package; and at least one row of intermediary terminals disposed between the inner terminal leads and the extended, outer terminal leads. Second wires bond the intermediary terminals to the semiconductor die; and third wires bond the intermediary terminals to the extended, outer terminal leads.

Wirebonding in the manufacturing of such a QFN semiconductor package is a complex process. One of the difficulties involving wirebonding is what is referred to in the industry as wire sweep. Wire sweep occurs when bonded wires are not correctly aligned in the horizontal plane (as opposed to wire sag, which is in the vertical orientation). Wire sweep can occur during the wire bonding step, during handling of the package after the wirebonding step, or during molding. Wire sweep is undesirable as it can affect electrical performance by changing the mutual inductance of adjacent wires and simultaneous switching noise. If the wires touch, they will result in a short circuit. Proper process development and setup can reduce or eliminate wire sweep during the wirebonding step. Automation can also reduce the risk in the handling step. Wire sweep during the molding step, however, is more difficult to eliminate, particularly with the finer pitch and more complex wiring schemes in today's advanced packages. Today's advanced package production wire bond pitches are 35-45 microns, with sub 35 microns pitch in development. Smaller wire diameters are used to achieve these finer pitches. Wire movement is most often caused when molding materials flow transversely across the bond wires during mold encapsulation.

Another disadvantage associated with wirebonding is that the wires may be long and as a result the overall thickness of the QFN semiconductor package may be thick by industry standards. It is therefore desirable to have a QFN semiconductor package having an alternative interconnection means.

### BRIEF SUMMARY

One or more embodiments of the disclosure may be implemented as a quad flat non-lead (QFN) semiconductor package having a die attach pad and a semiconductor die supported by the die attached pad. The semiconductor die includes a plurality of pads on an active surface thereof. An encapsulant encapsulates the semiconductor die. A redistribution layer includes a plurality of interconnections that electrically connect the pads of the semiconductor die to terminal leads of the package.

According to another aspect of the disclosure, there is provided a method of manufacturing a quad flat non-lead (QFN) semiconductor package. The method includes forming a die attach pad and a plurality of terminal leads out of an electrically conductive metal layer; and attaching a semiconductor die to the die attached pad. The semiconductor die includes a plurality of pads on an active surface thereof. The method further includes encapsulating the semiconductor die with an encapsulant; and electrically connecting the pads of the semiconductor die to the terminal leads via interconnections of a redistribution layer.

Other aspects and advantages of the disclosure will become apparent from the following detailed description, taken in conjunction with the accompanying drawings, illustrating by way of example the principles of the disclosure.

### BRIEF DESCRIPTION OF THE SEVERAL VIEWS OF THE DRAWINGS

The invention will be better understood with reference to the drawings, in which:

FIG. 1 is a cross sectional view of a QFN semiconductor package according to an embodiment of the invention;

FIG. 2 is a top view of an exemplary layout of the QFN semiconductor package in FIG. 1, showing interconnections of a redistribution layer connecting inner and outer terminal leads to pads of a semiconductor die; and

FIGS. 3-13 are schematic, cross-sectional diagrams showing an exemplary method for making the QFN semiconductor package of FIG. 1.

### DETAILED DESCRIPTION

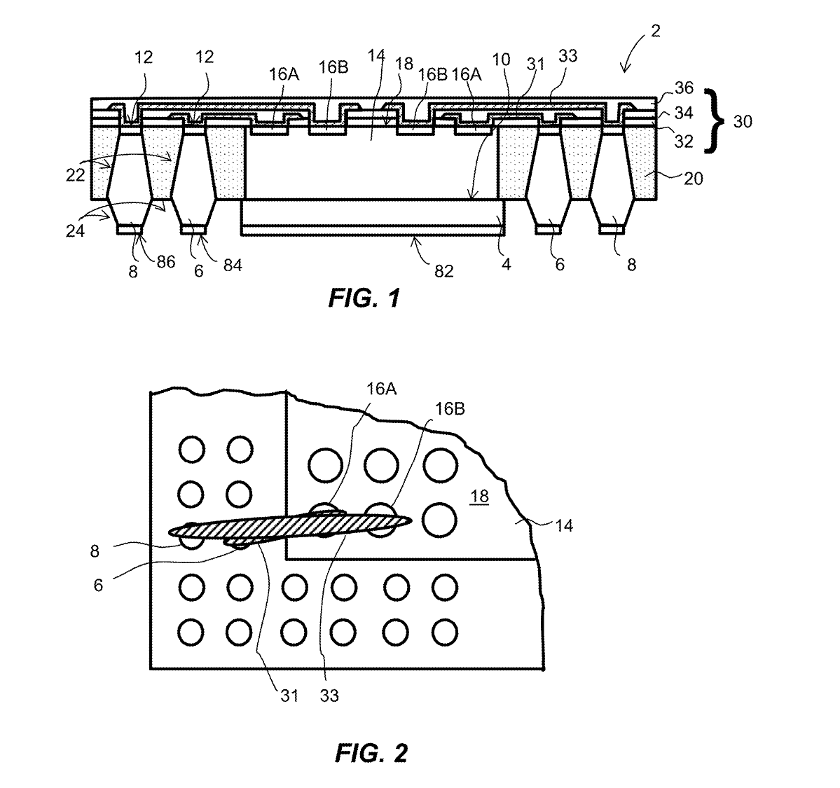

As shown in the drawings for purposes of illustration, one embodiment of the invention may be embodied in a novel quad flat non-lead (QFN) semiconductor package. The package may include electrical connections with limited use of or without using wirebonds and thus free from manufacturing problems associated therewith. Referring to FIG. 1, a QFN semiconductor package generally includes a die attach pad and a plurality of terminal leads. The QFN semiconductor package further includes a semiconductor die that is supported by the die attached pad. The semiconductor has multiple connection pads on an active surface thereof. The QFN package also includes an encapsulant that encapsulates the semiconductor die and portions of the terminal leads. The QFN package further includes a redistribution layer (RDL) including interconnections that electrically connect the connection pads of the semiconductor die and the terminal leads.

Specifically, FIG. 1 is a schematic, cross-sectional diagram illustrating a quad flat non-lead (QFN) semiconductor package 2 having a die attach pad 4 and multiple pillar-like terminal leads 6, 8 surrounding the die attach pad 4. It is to be appreciated, that the semiconductor package may include just one terminal lead 6 or 8 proximate any number of sides of the die attach pad 4, including just one side. In one embodiment as shown in FIG. 1, there are two rows of terminal leads 6, 8 adjacent each side of a square-shaped die attach pad 4. At least one row of inner terminal leads 6 is disposed adjacent to the die attach pad 4. And at least one row of outer terminal leads 8 is disposed along a periphery of the QFN semiconductor package. The die attach pad 4 has a substantially flat die attach surface 10. The terminal leads 6, 8 have respective interconnection surfaces 12 on a plane that is offset from the die attach surface 10. The QFN semiconductor package 2 further includes a semiconductor die 14 that is supported by the die attach pad 4 on the die attach surface 10 thereof. The semiconductor die 14 may be attached to the die attach surface 10 via any suitable adhesive, double sided tape, solder (not shown), or any suitable material for adhering the die 14 to the die attach surface 10. The semiconductor die 14 includes multiple pads 16A, 16B on an active surface 18 thereof. These pads 16A, 16B are electrically connected to an electrical device, such as an integrated circuit (not shown) formed in the semiconductor die 14.

The QFN package 2 further includes an encapsulant 20 that encapsulates the semiconductor die 14 and top portions 22 of the terminal leads 6, 8. The semiconductor die 14 and the terminal leads 6, 8 are held in their respective positions within the package 2 by the encapsulant 20 and are protected from external environments. In one embodiment, the encapsulant 20 may be any suitable mold compound, such as but not limited to epoxy resin, phenolic resin, polyester resin. In other embodiments, the encapsulant 20 may be of any suitable photoresist material. The base portions 24 of the terminal leads 6, 8 and the base of the die attach pad 4 are left exposed. In this embodiment, the surfaces of the pads 16A, 16B and the terminal leads 6, 8 that are to be electrically connected are at least substantially co-planar. In these embodiments, the die attach pad 4 and the plurality of terminal leads 6, 8 are fabricated out of an electrically conductive material, including a metal layer, such as a copper sheet, a copper alloy sheet, etc.

The QFN package 2 further includes a redistribution layer (RDL) 30 supported by the encapsulant 20. The redistribution layer 30 includes interconnections 31, 33 that electrically connect the pads 16A, 16B of the semiconductor die 14 to the terminal leads 6, 8. FIG. 2 is a partial top view of an exemplary layout of the QFN semiconductor package in FIG. 1, showing interconnections 31, 33 connecting the inner and outer terminal leads 6, 8 to the pads 16A, 16B of the semiconductor die 14. The pads 16A on the semiconductor die 14 are connected to the inner terminal leads 6 through interconnections 31. The pads 16B on the semiconductor die 14 are connected to the outer terminals 8 through the interconnections 33. In this exemplary layout, the interconnections 32 and 34 are shown crossing each when viewed from the top of the package 2 and thus have to be implemented at different layers, but this is not to be construed to be limited as such; other layout configurations are also possible as are known to those skilled in the art.

In some embodiments, such as in the embodiment where the encapsulant 20 is a mold compound, the redistribution layer 30 may include a first, second and third dielectric layers 32, 34, 36. The inner layer and outer layer interconnections 31, 33 are sandwiched between the first and second dielectric layers 32, 34, and the second and third dielectric layers 34, 36 respectively. The first, second, and third dielectric layers 32, 34, 36 provide electrical isolation for the inner and outer layer interconnections 31, 33.

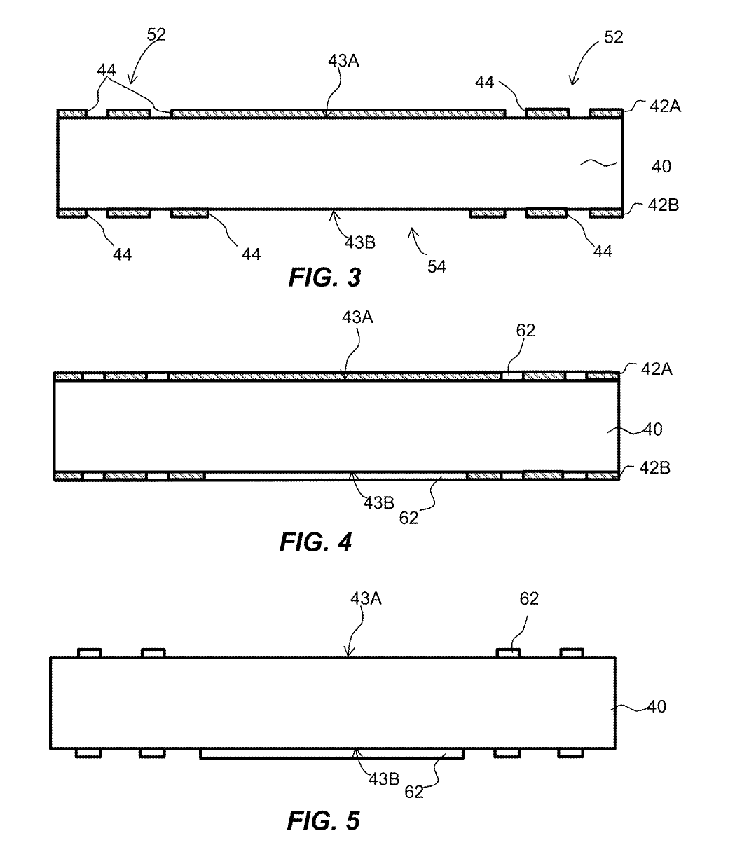

One embodiment for manufacturing the package 2 is next described with reference to FIGS. 3-13, which are schematic, cross-sectional diagrams showing an exemplary method for making the QFN semiconductor package 2 of FIG. 1, wherein like reference numerals designate like regions, layers or elements. As shown in FIG. 3, a conductive metal layer such as a copper carrier 40 is provided. A first patterned photoresist film 42A and a second patterned photoresist film 42B are formed respectively on a first side 43A and a second side 43B, opposite the first side 43A, of the copper carrier 40 to create apertures 44 that define lead array patterns 52 and a die attach pad 4 pattern 54 thereon.

As shown in FIG. 4, a deposition process, such as plating, is carried out to fill the apertures 44 on the two opposite sides 43A, 43B of the copper carrier 40 with a bondable metal layer 62 such as nickel, gold, a combination thereof, or any bondable conductive material. As shown in FIG. 5, the patterned photoresist film 42A and the patterned photoresist film 42B are stripped off to expose portions of the surface of the copper carrier 40 that are not covered by the metal layer 62.

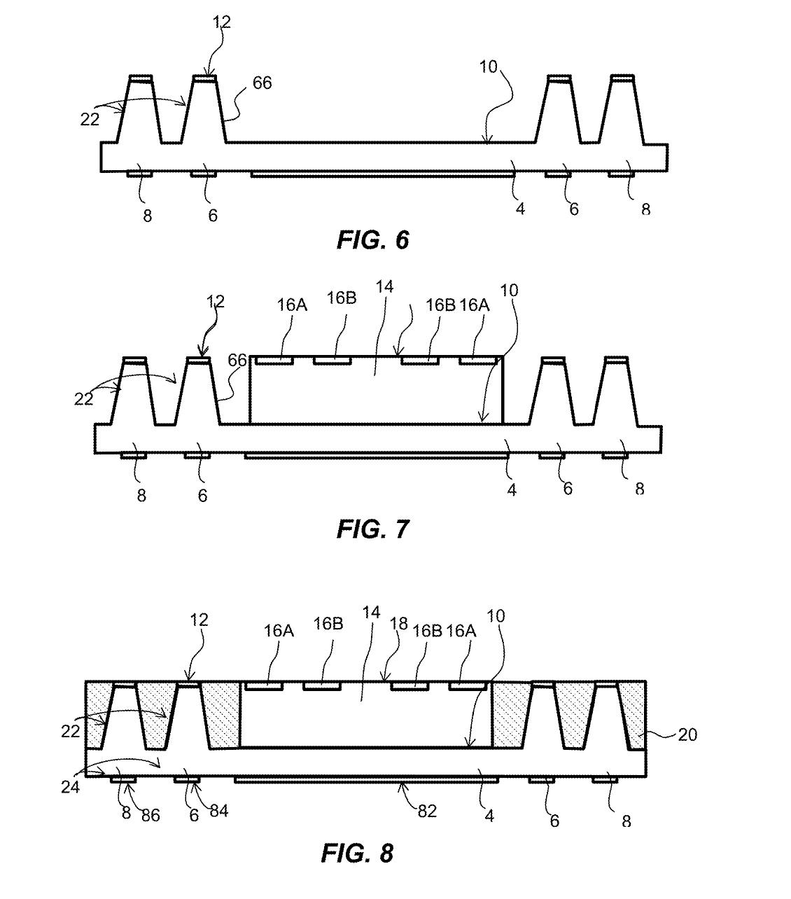

As shown in FIG. 6, a copper etching process is performed to half etch the exposed portion of the copper carrier 40 from the first side 43A. In this etching process, the top portions 22 of the terminal leads 6, 8 are formed and a recess 66 that exposes a die attach surface 10 of the die attach pad 4 is formed on the first side 43A. During this copper etching process, the bondable metal layer 62 acts as an etching hard mask for preventing the copper material thereunder from being etched away. In one embodiment, the depth to which the copper carrier 40 is etched is approximately the height of the semiconductor die 14. The exposed surfaces of the bondable metal layer 62 define interconnection surfaces 12 of the terminal leads 6, 8. According to this embodiment, the steps described through

FIGS. 3-6 may be performed in a leadframe manufacturing factory using technology well known to those skilled in the art.

As shown in FIG. 7, a semiconductor die 14 is mounted inside the recess 66, for example, by surface mount technology (SMT) or any other suitable methods, including but not limited to, attaching the semiconductor die to the top surface 10 of the die attach pad 4 using a layer of adhesive, double sided tape, or any suitable material (not shown). The semiconductor die 14 has a top active surface 18 with multiple connection pads 16A, 16B, four of which are shown. In one embodiment, when mounted on the die attach pad 4, the top surface of the connection pads 16A, 16B and the interconnection surfaces of the terminal leads 6, 8 are substantially co-planar.

As shown in FIG. 8, a molding process is next performed. The semiconductor die 14, and the first side 43A of the copper carrier 40 are encapsulated with an encapsulant 20. The encapsulant 20 is an insulative material that is configured to protect conductive features enclosed therein. In one embodiment, the encapsulant 20 may be a mold compound made up of epoxy resins. However, in other embodiments, the encapsulant 20 may be of a photoresist material or the like. The encapsulant 20 fills the voids between the terminal leads 6, 8 and the semiconductor die 14 forms a surface and exposes surfaces of the interconnection surfaces 12 of the terminal leads 6, 8 and the connection pads 16A, 16B. If the molding process is not well controlled and the encapsulant 20 covers the surfaces of the terminal leads 6, 8 and the semiconductor die 14 during the molding process, an additional step for removing the mold compound, such as by grinding, may be necessary to expose the surfaces. Grinding may result in a planar top surface of the encapsulant 20.

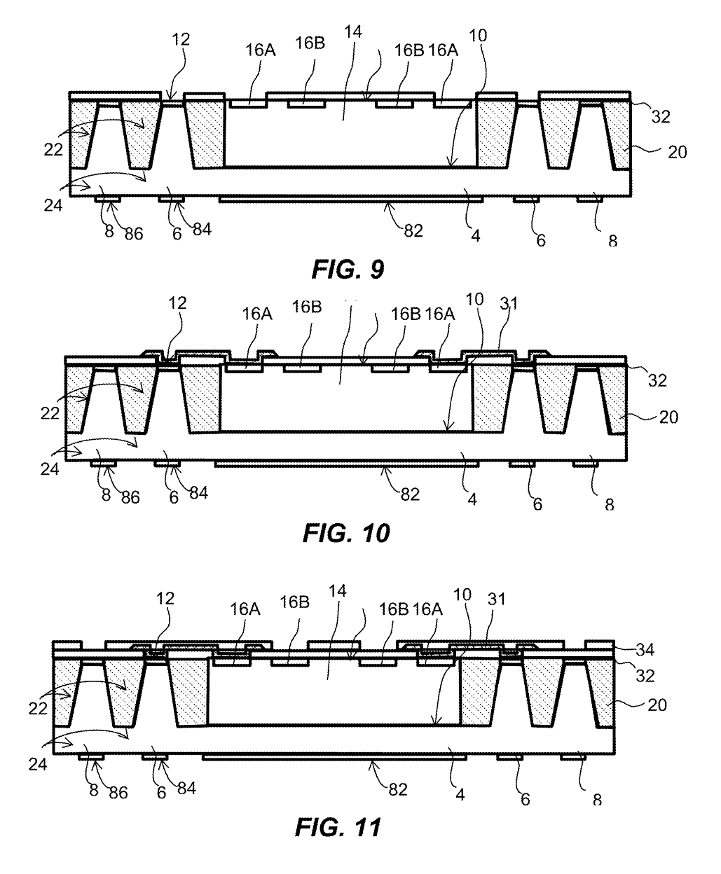

After the encapsulant 20 is formed, the redistribution layer 30 is formed in several stages on the surface of the encapsulant 20 as shown in FIGS. 9-13. First, as shown in FIG. 9, the first dielectric layer 32 is deposited on the surface of the mold cap 20 and patterned, to form a first plurality of contact apertures 70. FIG. 10 shows a first conductive layer 31 that is deposited over the first dielectric layer 32, filling the contact apertures 70 and the surface of the exposed first dielectric layer 32, and patterned to form the interconnections 31 (or conductive traces) extending over the first dielectric layer 32 for connecting the connection pads 16A, 16B of the semiconductor die 14 to respective terminal leads 6. If the encapsulant 20 is of photoresist material, encapsulating as shown in FIG. 8 may include covering the interconnection surfaces 12 of the terminal leads 6, 8 and the connection pads 16A, 16B with the photoresist material so that the deposition of the dielectric layer 32 is made redundant. In this case, the top layer of the mold cap 20 may be patterned, for example by etching, to form the plurality of contact apertures 70 without the need to first deposit the dielectric layer 32.

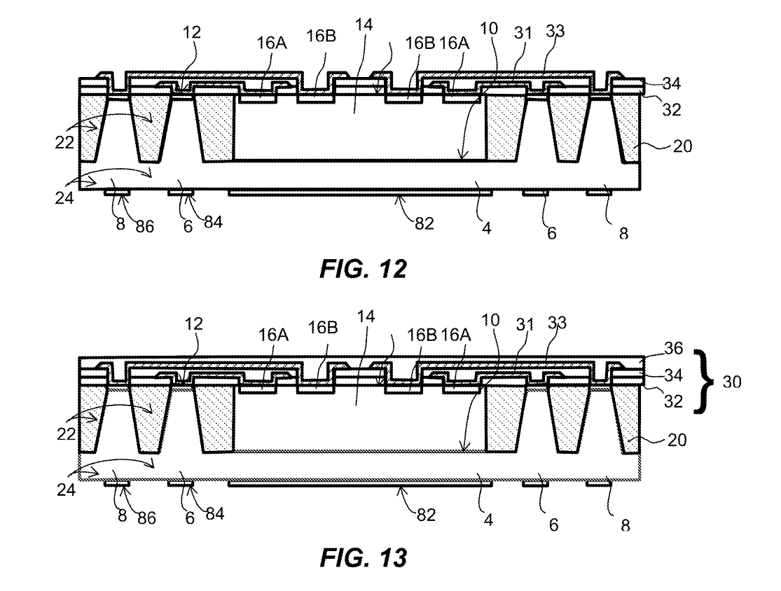

FIG. 11 shows the second dielectric layer 34 formed over the first conductive layer 31, and patterned to form a second plurality of contact apertures 72. As shown in FIG. 12, a second conductive layer 33 is formed over the second dielectric layer 34, filling the contact apertures 72 and the surface of the exposed second dielectric layer 34, and patterned to form the second plurality of interconnections 33 (or conductive traces), extending over the second dielectric layer 34 for connecting the pads 16B to respective terminal leads 8. A third dielectric layer 36 is then formed over the second conductive layer to complete the redistribution layer 30, as shown in FIG. 13. Although two conductive layers 31, 33 are described, those skilled in the art would recognize that the number of conductive layers are determined by the number and manner of interconnections to be made between the pads of the semiconductor die and the terminal leads. It is possible that only a single conductive layer, or three or more conductive layers are required to form the required interconnections.

After the RDL 30 is formed, a copper etching process is performed to half etch the exposed copper carrier 40 to electrically isolate the die attach pad 4 and the leads 6, 8. In the illustrated embodiment, the bondable metal layer 62 from the second side 43B is used as a mask layer, to thereby complete the forming of the die attach pad 4, inner terminal leads 6, and the outer terminal leads 8 which prior to this step are all physically and therefore electrically connected. The die attach pad 4, the inner terminal leads 6 and the outer terminal leads 8 have exposed bottom surfaces 82, 84 and 86 respectively, which are substantially coplanar. The exposed bottom surfaces 82, 84 and 86 of the die attach pad 4, the inner terminal leads 6 and the outer terminal leads 8 respectively are eventually bonded to a printed circuit board (not shown) during use.

Advantageously, the QFN semiconductor package 2 described above is bondwire-free, relying instead on a redistribution layer for making interconnections between pads of a semiconductor die and terminal leads. Such a QFN semiconductor package can be made thinner than conventional QFN semiconductor packages employing wirebonds.

Although the present invention is described as implemented in the above described embodiment which includes only two rows of terminal leads on each side of the die attach pad, it is not to be construed to be limited as such. For example, the invention may be implemented in an embodiment with any number of rows including a single row and three rows of terminal leads with an intermediary terminal leads between the inner and outer terminal leads. As another example, the die attach pad may include a power or ground ring (not shown) that is integrally formed with the die attach pad and is annular-shaped. The power or ground ring 11 may be continuous or discontinuous.

The various embodiments described above can be combined to provide further embodiments. All of the U.S. patents, U.S. patent application publications, U.S. patent application, foreign patents, foreign patent application and non-patent publications referred to in this specification and/or listed in the Application Data Sheet are incorporated herein by reference, in their entirety. Aspects of the embodiments can be modified, if necessary to employ concepts of the various patents, application and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A semiconductor package comprising:
a die attach pad;
a semiconductor die on the die attached pad, the semiconductor die including an active surface with a plurality of pads;
a plurality of terminal leads;
an encapsulant that encapsulates the semiconductor die and portions of side surfaces of the terminal leads; and
a redistribution layer over the encapsulant, the redistribution layer including a plurality of interconnections electrically connecting the pads to the terminal leads.

2. The semiconductor package according to claim 1, wherein the die attach pad and the plurality of terminal leads are formed from an electrically conductive metal layer.

3. The semiconductor package according to claim 1, wherein the encapsulant is photoresist.

4. The semiconductor package according to claim 1, wherein the encapsulant is mold compound.

5. The semiconductor package according to claim 1, wherein surfaces of the pads and the terminal leads are substantially co-planar.

6. The semiconductor package according to claim 1, wherein the plurality of leads comprises a first row of inner terminal leads disposed adjacent to the die attach pad and a second row of outer terminal leads disposed along a periphery of the semiconductor package.

7. The semiconductor package according to claim 1, wherein the interconnections comprises conductive traces.

8. A method of manufacturing a semiconductor package, the method comprising:
attaching a semiconductor die to a die attached pad of a conductive layer, the conductive layer further including a plurality of terminal leads proximate at least one side of the die attach pad, the semiconductor die having an active surface that includes a plurality of pads;
encapsulating side surfaces of the semiconductor die and first portions of side surfaces of the terminal leads with an encapsulant; and
electrically connecting the pads to the terminal leads via interconnections of a redistribution layer.

9. The method according to claim 8, wherein encapsulating the side surfaces of the semiconductor die and first portions of the side surfaces of the terminal leads with the encapsulant comprises encapsulating upper and side surfaces of the semiconductor die and upper and the first portions of the side surfaces of the terminal leads with photoresist, and further comprising etching the photoresist to expose the upper surfaces of the pads and the terminal leads for electrical interconnections.

10. The method according to claim 8, further comprising forming a die attach pad and a plurality of terminal leads in the conductive layer prior to attaching the semiconductor die to the die attach pad.

11. The method according to claim 10, wherein forming the die attach pad and the plurality of terminal leads comprises:
etching a first surface of the conductive layer to form a first side of the die attach pad and first ends of the plurality of terminal leads; and
etching a second surface of the conductive layer to form a second side of the die attach pad and second ends of the plurality of terminal leads after electrically connecting the pads to the terminal leads via interconnections of the redistribution layer.

12. The method according to claim 8, further comprising removing the encapsulant to expose surfaces of the pads and terminal leads for electrical interconnection.

13. The method according to claim 12, wherein removing the encapsulant to expose surfaces of the pads and terminal leads comprises grinding the encapsulant and forming a substantially planar surface.

14. The method according to claim 8 further comprising etching a second surface of the conductive layer to electrically isolate the terminal leads from each and the die attach pad from the terminal leads.

15. A semiconductor package comprising:
a die attach pad having a first surface;
a semiconductor die secured to the first surface of the die attached pad, the semiconductor die including an active surface with a plurality of pads;
a plurality of terminal leads proximate at least one side of the die attach pad;
an encapsulant along side surfaces of the semiconductor die and a portion of side surfaces of the terminal leads, the encapsulant, the semiconductor die, and the terminal leads forming a substantially planar surface; and
a redistribution layer located on the substantially planar surface, the redistribution layer including a plurality of interconnections, each of the interconnections electrically connecting one of the plurality of pads to at least one of the plurality of terminal leads.

16. The semiconductor package according to claim 15 wherein the encapsulant is one of photoresist and mold compound.

17. The semiconductor package according to claim 16 wherein the terminal leads are located one each side of the die attach pad.

18. The semiconductor package according to claim 15 wherein side surface of the die attach pad are not covered with the encapsulant.

19. The semiconductor package according to claim 15 wherein a perimeter of the first surface of the die attach pad is covered with the encapsulant.
